(19) United States
(12) Patent Application Publication
(10) Pub. No.: US 2024/0355379 A1
(43) Pub. Date: Oct. 24, 2024

(54) Voltage Range for Training Physical Memory

(71) Applicant: Advanced Micro Devices, Inc., Santa Clara, CA (US)

(72) Inventors: Anwar Parvez Kashem, Sudbury, MA (US); Glennis Eliagh Covington, Austin, TX (US); Alicia Wen Ju Yurie Leong, Austin, TX (US)

(73) Assignee: Advanced Micro Devices, Inc., Santa Clara, CA (US)

(21) Appl. No.: 18/305,080

(22) Filed: Apr. 21, 2023

(51) Int. Cl. G11C 11/4096; G11C 11/4074; G11C 11/4076

(52) U.S. Cl. CPC G11C 11/4096; G11C 11/4074; G11C 11/4076

(57) ABSTRACT

Voltage range for training physical memory is described. A device is configurable to include a PHY having an interface to support communication of command signals and data with a physical memory. The PHY implements a training mode to train the interface over a training voltage range to communicate the command signals or data and an operational mode to use the trained interface to communicate the command signals or data over an operational voltage range that is smaller than the training voltage range.

### BACKGROUND

The amount of data and a speed at which data is accessible from physical memory by a computing device is a driving factor on overall device operation. Because of this operational effect, techniques are continually developed to increase this speed, accuracy, and storage capability of physical memory, an example of which includes dynamic random access memory (DRAM). This continued development, however, has encountered additional challenges that affect when data is accessible from the physical memory, challenges resulting from environmental conditions (e.g., heat) on the operation of the physical memory, and so forth.

### BRIEF DESCRIPTION OF THE DRAWINGS

The detailed description is described with reference to the accompanying figures.

FIG. 1 is a block diagram of a non-limiting example system configured to employ training and operational mode techniques described herein.

FIG. 2 is a block diagram of a non-limiting example system showing configuration of a PHY of FIG. 1 in greater detail as communicatively coupled via an interface to physical memory implemented using a plurality of dynamic random access memory (DRAM) devices.

FIG. 3 is a block diagram of a non-limiting example system showing a training voltage range of a training mode and an operational voltage range of an operational mode.

FIG. 4 is a block diagram of a non-limiting example system showing individualized programmability of dynamic random access memory (DRAM) devices to implement a training voltage range of a training mode and an operational voltage range of an operational mode.

FIG. 5 depicts a procedure in an example implementation of training and operation mode voltage ranges for an interface communicatively coupling a PHY with physical memory.

### DETAILED DESCRIPTION

### Overview

A PHY, also referred to as a physical layer, is typically implemented as an integrated circuit to provide a physical interface in hardware between a processing unit (e.g., a central processing unit) and physical memory, e.g., dynamic random access memory. The PHY is responsible for converting digital data from the processing unit into analog electrical signals that are transmitted over the physical interface to the physical memory. Likewise, the PHY is also responsible for converting analog electric signals received over the physical interface into digital data for use by the processing unit.

As part of implementing the physical interface, training is performed by the PHY (e.g., at startup and is adjustable during operation) to set parameters of the physical interface in order to optimize communication. Training is usable by the PHY to address differences in design of the processing unit and the physical memory, changing operational conditions (e.g., temperature), and so forth. Examples of parameters set as part of training include impedance calibration which is set by adjusting termination resistance values in the PHY and the physical memory. Impedance calibration is used to match impedance of transmitters and receivers utilized by the physical interface between the PHY and the physical memory to reduce signal reflections and maintain signal integrity. Voltage and timing reference parameters are also set as part of training by adjusting voltage levels and clock phase to establish a common voltage and timing reference for signals communicated between the PHY and the physical memory. Read and write leveling is set as part of training by adjusting a relative timing of clock and data signals over the physical interface to coordinate data sampling. A data strobe signal (DQS), for instance, is aligned with data signals (DQ) during reading operations to define “when” the data signals are sampled based on the data strobe signal.

Conventional techniques used to perform training by the PHY, however, are inefficient, consume a significant amount of time to perform, and result in increased power consumption. Conventional training technique examples involve a brute force approach or rely on a priori knowledge of the devices. In a conventional brute force approach, a range of possible values is tested by the PHY for each of the parameters, e.g., for impedance, voltage and timing references, equalization settings, clock phase, and so on as described above. Consequently, the PHY is tasked with comparing and evaluating each combination of the parameters in order to identify an optimal combination that yields the best results, e.g., a highest communication speed that also supports reliable communication. A conventional brute force approach, therefore, may consume significant resources in evaluating a potentially large number of combinations of parameters.

An a priori approach relies on careful measurements and characterization of components in order to set the parameters. In an a priori approach, for instance, impedances and data throughput are measured and characterized for physical connections between the PHY and the physical memory. However, such measurements and resulting characterization are difficult to accurately achieve in real world scenarios due to process variations in manufacturing the components and may vary due to changing environmental conditions encountered in typical operation of the components.

To solve these technical problems, a PHY implements a training mode to train parameters as part of a physical interface that supports communication of data and command signals between the PHY and the physical memory. An operational mode is then used once the parameters of the physical interface are set by the training mode to support increased signal speed of the data and command signals.

In the training mode, a first range of voltages are utilized by the PHY to determine values for parameters as described above. For example, a voltage reference (Vref) parameter has a value that is learned as part of training. The voltage reference parameter defines a stable reference voltage that is usable as part of differential signaling as a midpoint reference voltage to distinguish between a high logic level and a low logic level, e.g., between a one and a zero based on whether a detected voltage level is above or below the reference voltage. Therefore, training of the voltage reference parameter by the PHY involves determining a reference voltage, at which, to set as the voltage reference parameter.

In order to determine the value for the voltage reference (Vref) parameter, the PHY sets a first range of voltages as part of the training mode. The first range of voltages are set by the PHY by modifying termination states (e.g., use of termination resistors to electrically terminate transmission lines) and output impedances to be weakly terminated at the physical memory to support a “rail-to-rail” voltage swing, e.g., from 0.1 volts to 1.1 volts. An initial value for the voltage reference (Vref) parameter is then set within this first range “which is known to be good” and then optimized along with training other parameters of the physical interface as described above.

Once the value for the voltage reference (Vref) parameter and other parameters are set during the training mode, the PHY initiates an operational mode having a reduced signal range to support increased signal speed, e.g., from 0.85 volts to 1.1 volts. Changes in voltage levels over the increased voltage range of the training mode, for instance, take a longer time to perform than changes in voltage levels over a decreased voltage range in the operational mode. During training as performed in the training mode, however, the larger voltage range acts to increase efficiency in training of the physical interface (e.g., through use of a Vref that is known to be good) because signal speed at that point in time has a lower priority than achieving a trained interface overall. Once training is completed, a decreased voltage range is used in an operational mode to increase signal speed. Further discussion of these and other examples is included in the following sections and shown in corresponding figures.

In some aspects, the techniques described herein relate to a device including a physical layer (PHY) having an interface to support communication of command signals and data with a physical memory, the PHY implementing a training mode to train the interface over a training voltage range to communicate the command signals or data, and an operational mode to use the trained interface to communicate the command signals or data over an operational voltage range that is smaller than the training voltage range.

In some aspects, the techniques described herein relate to a device, wherein the interface implements an interface protocol that employs a parameter used to control communication of the command signals and the data with the physical memory.

In some aspects, the techniques described herein relate to a device, wherein the training mode detects a value of the parameter of the interface protocol and the operational mode uses the detected parameter.

In some aspects, the techniques described herein relate to a device, wherein the parameter involves signal or timing.

In some aspects, the techniques described herein relate to a device, wherein the parameter involves voltage reference (Vref) training, command training, clock-to-strobe leveling, write-leveling training, or strobe-to-DQ training of the interface protocol.

In some aspects, the techniques described herein relate to a device, wherein the parameter involves how signals are propagated from one physical memory component of the physical memory to another physical memory component of the physical memory.

In some aspects, the techniques described herein relate to a device, wherein the training mode is configured to modify termination states or output impedances of the PHY to implement the training voltage range of the training mode.

In some aspects, the techniques described herein relate to a device, wherein the training mode is further configured to modify termination states or output impedances of the physical memory to implement the training voltage range as part of the training mode.

In some aspects, the techniques described herein relate to a device, wherein the training mode operates at a frequency that is lower than a frequency of the operational mode.

In some aspects, the techniques described herein relate to a device, wherein the PHY includes another interface to transfer command signals and data with a memory controller.

In some aspects, the techniques described herein relate to a device, wherein the PHY is implemented in hardware as part of an integrated circuit, the interface is bidirectional, and the physical memory is a dynamic random access memory (DRAM).

In some aspects, the techniques described herein relate to a system including a memory controller, a dynamic random access memory (DRAM), and a physical layer (PHY) providing a communicative coupling with the memory controller and the DRAM, the PHY implementing a training mode to detect a value of a parameter as part of training an interface between the PHY and the DRAM, the training mode operational over a training voltage range, and an operational mode to use the detected value for the parameter to implement the interface between the PHY and the DRAM, the operational mode operational over an operational voltage range that is smaller than the training voltage range.

In some aspects, the techniques described herein relate to a system, wherein the training mode is configured to modify termination states and output impedances of the PHY to implement the training voltage range of the training mode.

In some aspects, the techniques described herein relate to a system, wherein the training mode is further configured to modify termination states and output impedances of the dynamic random access memory (DRAM) to implement the training voltage range as part of the training mode.

In some aspects, the techniques described herein relate to a system, wherein the parameter includes signal or timing.

In some aspects, the techniques described herein relate to a system, wherein the parameter includes voltage reference (Vref) training.

In some aspects, the techniques described herein relate to a system, wherein the parameter includes command training, clock-to-strobe leveling, or strobe-to-DQ training.

In some aspects, the techniques described herein relate to a method including setting a training mode to train an interface between a physical layer (PHY) and physical memory to communicate command signals or data, the training mode employing a training voltage range, setting an operational mode to operate the trained interface between the PHY and the physical memory to communicate command signals or data, the operational mode employing an operational voltage range that is less than the training voltage range.

In some aspects, the techniques described herein relate to a method, wherein the training mode is configured to modify termination states and output impedances of the PHY to implement the training voltage range of the training mode.

In some aspects, the techniques described herein relate to a method, wherein the training of the interface is voltage reference (Vref) training.

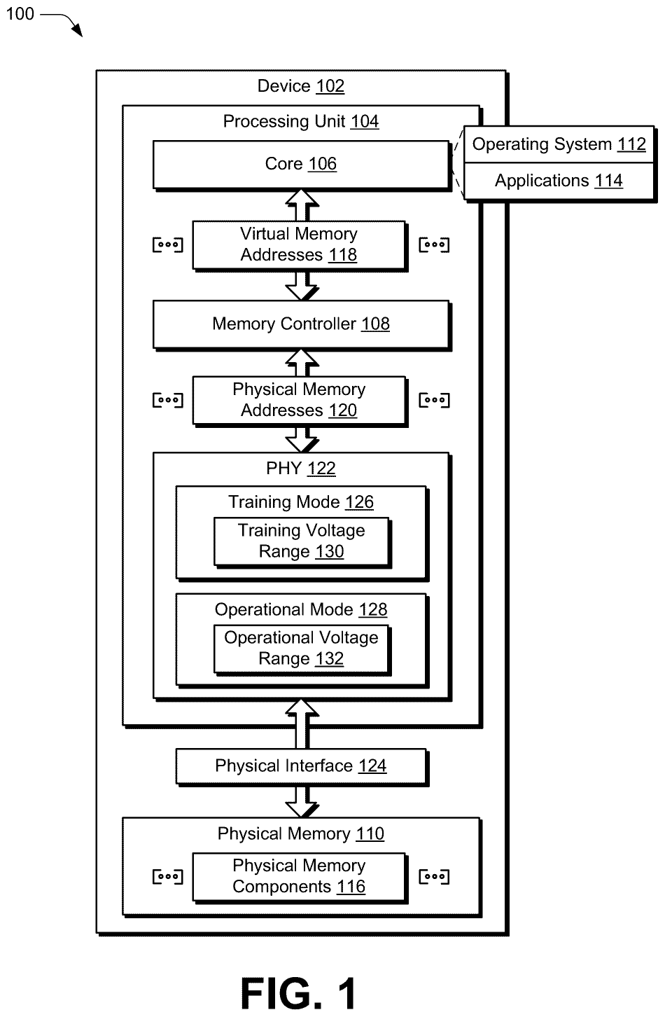

FIG. 1 is a block diagram of a non-limiting example system 100 configured to employ the training and operational mode techniques described herein. These techniques are usable by a wide range of device 102 configurations. Examples of those devices include, by way of example and not limitation, computing devices, servers, mobile devices (e.g., wearables, mobile phones, tablets, laptops), processors (e.g., graphics processing units, central processing units, and accelerators), digital signal processors, interference accelerators, disk array controllers, hard disk drive host adapters, memory cards, solid-state drives, wireless communications hardware connections, Ethernet hardware connections, switches, bridges, network interface controllers, and other apparatus configurations. Additional examples include artificial intelligence training accelerators, cryptography and compression accelerators, network packet processors, and video coders and decoders. It is to be appreciated that in various implementations, the techniques described herein are usable using any one or more of those devices listed just above and/or a variety of other devices without departing from the spirit or scope of the described techniques.

The illustrated example of the device 102 includes a processing unit 104 having a core 106 that is communicatively coupled (e.g., via a bus) to a memory controller 108 that is communicatively coupled (e.g., via a bus) to physical memory 110. The processing unit 104 in configured in hardware to execute instructions as arithmetic and logical operations, configured to control input/output devices, and manage data storage and retrieval. The processing unit is configurable as a central processing unit, a graphics processing unit, and other processing units including digital signal processing, tensor processing unites, and field-programmable gate arrays. The core 106 as part of the processing unit 104 is configurable in a variety of ways to execute instructions as part of the processing unit 104 to perform operations, e.g., in hardware as one or more integrated circuits to execute an operating system 112, applications 114, and so forth. Other configurations are also contemplated, examples of which include parallel processors, graphics processing units, and so forth.

In one example, the memory controller 108 is configured (e.g., in hardware as an integrated circuit, as a microcontroller configured to execute instructions, etc.) for I/O device usage, e.g., as an input output memory management unit (IOMMU). The memory controller 108 is configurable as part of the processing unit 104 itself (e.g., as an on-die memory controller) or configurable as a separate component on a motherboard of the device 102. Although a single instance of physical memory 110 is illustrated, the physical memory 110 is representative of a variety of types of physical memory (e.g., implemented in hardware) that are implementable together as a plurality of physical memory components 116, e.g., volatile and non-volatile memory.

The memory controller 108 is configured to control access between the core 106 and the physical memory 110. The memory controller 108, for instance, is configurable in hardware using one or more integrated circuits, supports execution of instructions through configuration as a microcontroller, and so forth. In the illustrated example, the memory controller 108 supports use of virtual memory addresses 118 of a virtual address space by the core 106 along with physical memory addresses 120 of a physical address space of the physical memory 110. Virtual memory is a technique to manage use of shared physical memory 110, e.g., by a plurality of cores. Virtual memory supports a variety of different functionality. Examples of this functionality include expansion of an amount of storage made available to applications beyond that which is actually available in the physical memory, offload memory management from the application 114 and operating system 112, use of a variety of different types of memory without the applications being made aware, support memory optimization, address memory fragmentation, and so forth.

A physical layer (PHY) 122 is employed by the processing unit 104 to implement a physical interface 124 with the physical memory 110. The PHY 122, for instance, is configurable as hardware in an integrated circuit (e.g., dedicated or included as part of the processing unit 104) communicatively disposed between the processing unit 104 and the physical memory 110. The PHY 122 is configured to support interoperability between the processing unit 104 and physical memory 110, even when developed by different manufacturers. To do so, the PHY 122 defines signals, timing, and other parameters that are programmable as part of training to define how command signals and data are transmitted over the physical interface 124.

Training is performed by the PHY 122 (e.g., at startup and is adjustable during operation) to set parameters of the physical interface 124 in order to optimize communication. Examples of parameters set as part of training include impedance calibration which is set by adjusting termination resistance values in the PHY 122 and the physical memory 110. Impedance calibration is used to match impedance of transmitters and receivers utilized by the physical interface 124 between the PHY 122 and the physical memory 110 to reduce signal reflections and maintain signal integrity. Voltage and timing reference parameters are also set as part of training by adjusting voltage levels and clock phase to establish a common voltage and timing reference for signals communicated between the PHY 122 and the physical memory 110. Read and write leveling is set as part of training by adjusting a relative timing of clock and data signals over the physical interface 124 to coordinate data sampling. A data strobe signal (DQS), for instance, is aligned with data signals (DQ) during reading operations to define “when” the data signals are sampled based on the data strobe signal.

In order to maximize speed of communication of command signals and data over the physical interface 124, the PHY 122 supports a training mode 126 and an operational mode 128. The training mode 126 operates as a type of handshaking technique to determine values of programmable parameters that are to be used to implement the protocol.

Conventional techniques to perform training are performed in one of two ways as described above. In a first brute force example, a significant amount of trial and error is encountered as different values are set and tested for the parameters. This example encounters operational inefficiencies, delays, increased power consumption, and so on due to a large number of parameters being testing as well as a large number of values usable for those parameters. In a second example, an a priori approach is undertaken that relies on careful measurements and characterization of the processing units, physical memory, and the interface in between that is difficult to achieve in real world scenarios. This challenge is further exacerbated when confronted with changing environmental conditions.

To overcome these challenges, a training mode 126 is employed that uses a training voltage range 130 that is larger than an operational voltage range 132 used as part of the operational mode 128. In this way, decreased training time and increased accuracy is achieved during the training mode 126 while preserving faster communication speeds supported by the operational mode 128 as further described below.

During early stages of training performed by the training mode 126, for instance, a voltage reference (Vref) setting is not set. Therefore, asynchronous techniques are employed during initial training stages that do not use Vref until a value for Vref is determined. To decrease an amount of time spent in training, a training voltage range 130 is employed by the PHY 122 initially as part of training to support a “rail-to-rail” voltage swing. This voltage swing is used to define a minimum voltage that defines a logic one (VIHmin) and a maximum voltage that defines a logic zero (VILmax). This is performed by modifying termination states and output impedances of the physical interface 124 between the PHY 122 and the physical memory 110 to support this increased range, e.g., to be weakly terminated at the physical memory 110.

Once an asynchronous feedback portion of the training mode 126 is completed and a value for Vref is determined, the termination states and output impedances are returned by the PHY 122 to an operational voltage range 132. Therefore, the physical interface 124 once trained operates at increased signal speeds and improved efficiency using parameters that are learned during the training mode 126. As a result, an amount of time taken to perform an asynchronous part of the training in order to find a value for Vref is reduced and an operational mode is achieved in a decreased amount of time, thereby improving device operation.

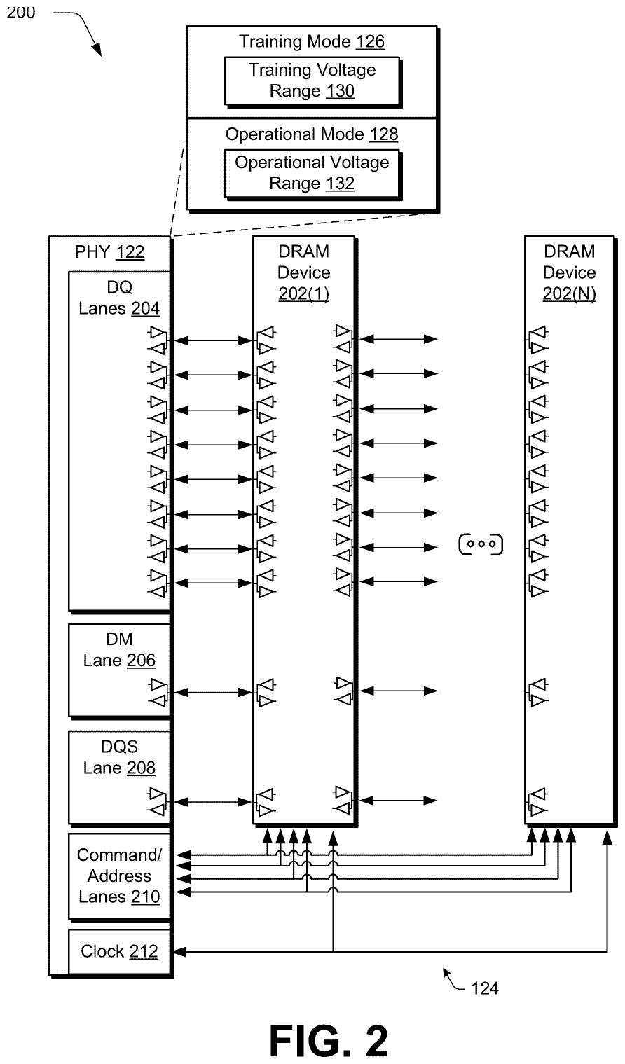

FIG. 2 is a block diagram of a non-limiting example system 200 showing configuration of the PHY 122 in greater detail as communicatively coupled via the physical interface 124 to physical memory 110 implemented using a plurality of dynamic random access memory (DRAM) devices 202(1), . . . , 202(N). The PHY 122 as illustrated includes a plurality of bidirectional transceivers that implement DQ lanes 204, a DM lane 206, a DQS lane 208, command/address lanes 210, and a clock 212. The DQ lanes 204 implement data signal transfer, e.g., via respective wires illustrated using bidirectional arrows. The DM lane 206 carries a data mask signal. The data mask signal is used to selectively enable or disable the writing of data into the memory from the DQ lanes 204. When the data mask signal is asserted (active), corresponding data bits are masked or ignored during a write operation thereby allowing the memory controller to selectively write data to specific memory locations without affecting adjacent locations. The DQS lane 208 implements a data strobe that transfers a clock signal for the DQ lanes 204 and the DM lane 206. The data strobe is used to control sampling of the DQ lanes 204 and DM lane 206, e.g., based on rising and falling edges of the signal. The data strobe, for instance, of the DQS lane 208 is used to control when a data signal is sampled from the DQ lane 206 in order to define a logic one or zero.

The command/address lanes 210 support communication of command signals to the DRAM device 202(1), e.g., to respective transceivers. A variety of types of command signals and associated addresses are sent from the PHY 122 using the command/address lanes 210, examples of which include maintenance, setup, and data bearing command signals such as “reads” and “writes.” For “reads” and “writes” the command signals are sent via the command/address lanes and data is transferred from the PHY 122 to the DRAM device 202(1) over the DQ lanes 204 in a write, which are sampled based on data strobe signals from the DQS lane 208. On the other hand, data is transferred from the DRAM device 202(1) to the PHY 122 over the DQ lanes 204 in a read command, which is also sampled based on data strobe signals from the DQS lane 208.

In some instances, a plurality of DRAM devices is communicatively coupled over the physical interface 124 of the PHY 122. This is implemented, in one example over a multidrop bus that is bidirectional to support communication with DRAM device 202(1), . . . , DRAM device 202(N). Use of a bidirectional multidrop bus, however, introduces challenges such as signal discontinuities and reflections caused by loads on opposing sides of the DRAM device 202(1). For example, a write from the PHY 122 to the DRAM device 202(N) involves awareness of a DRAM device 202(1) on the multidrop bus disposed in between the PHY 122 and the DRAM device 202(N), e.g., to terminate the bus to prevent unwanted signal reflections.

Training of the physical interface 124, however, involves a “chicken and the egg” problem. Training of one type of parameter, for instance, may be dependent on another type of parameter. Consequently, in practice training is confronted with ill-formed feedback (i.e., that is not formed as data packets involving a strobe and data bits) but rather asynchronous feedback defining a level having an unknown timing relationship. Further, training is typically dependent on ordering, such as to train the command/address lanes 210 before training the DQ lanes 204.

Consequently, initial training is performed by the PHY 122 without knowledge of a correct timing of the command/address lanes 210 and without correct voltage or time references for the transceivers that implement the physical interface 124. However, training by the PHY 122 is still dependent on feedback received from the DRAM devices and interpretation of that feedback. Conventional techniques to address this, as described above, involve brute force techniques involving a multitude of different input voltage levels, reference levels, and so forth to determine “what works.” On the other hand, a priori knowledge involves careful measurement of the hardware, the accuracy of which is limited by manufacturing accuracy, variance, and environment conditions, e.g., heat.

Accordingly, the PHY 122 in this example utilizes a training voltage range 130 during the training mode 126 to provide a larger swing in voltages and thus have increased detectability. The PHY 122 does so by modifying termination states and output impedances of the physical memory 110 as well as for the PHY 122 itself. The termination states and output impedances, for instance, are set using a value at a corresponding transistor. Setting the value at the corresponding transistor forces the signal to have a wider swing (e.g., rail-to-rail) in the training voltage range 130. Once training is completed (e.g., a portion of the training involving asynchronous feedback) the PHY 122 returns to an operational voltage range 132 using parameters detected during the training mode 126 having a lesser amount of voltage swing to support higher data transfer speeds.

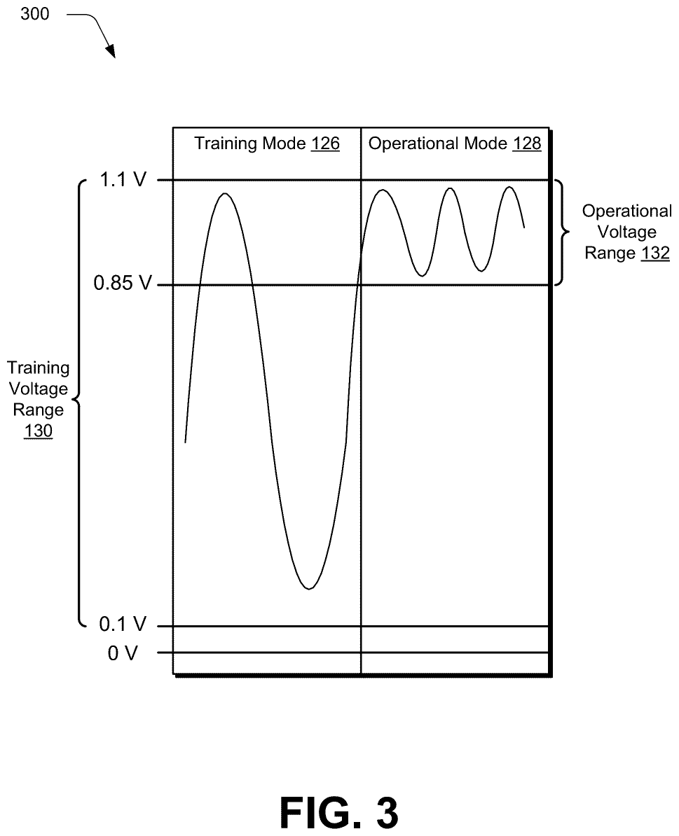

FIG. 3 is a block diagram of a non-limiting example system 300 showing a training voltage range 130 of a training mode 126 and an operational voltage range 132 of an operational mode 128. In the illustrated example, voltage ranges from zero volts to 1.1 volts are shown for the physical interface 124 between the physical memory 110 and the PHY 122.

In an operational mode 128, the operational voltage range 132 is defined between 0.85 volts and 1.1 volts. This is used to support higher communication frequencies (in a Gigahertz range) by minimizing voltage swings that are detected e.g., a minimum voltage that defines a logic one (VIHmin) and a maximum voltage that defines a logic zero (VILmax). This is because a shorter voltage swing is performable in a shorter amount of time to change a voltage on a wire implementing the physical interface 124, and therefore supports this higher frequency.

In the training mode 126, on the other hand, communication speed is not a driving factor and thus is performable at reduced frequencies, e.g., in a Megahertz range. Based on this insight, a training voltage range 130 is set by the PHY 122 between 0.1 volts and 1.1 volts. This is performed by modifying parameters of termination strengths and output impedances of the DRAM devices 202(1)-202(N) and the PHY 122, e.g., set via respective bits using associated transistors.

With the larger swing of the training voltage range 130 of the training mode 126, for instance, a “guaranteed-to-work” value for a voltage reference (Vref) is settable for use as part of training regardless of process variations and environmental conditions, which is not possible in conventional techniques. These techniques also support interleaving of training modes 126 with operational modes 128, e.g., to address changing environmental conditions.

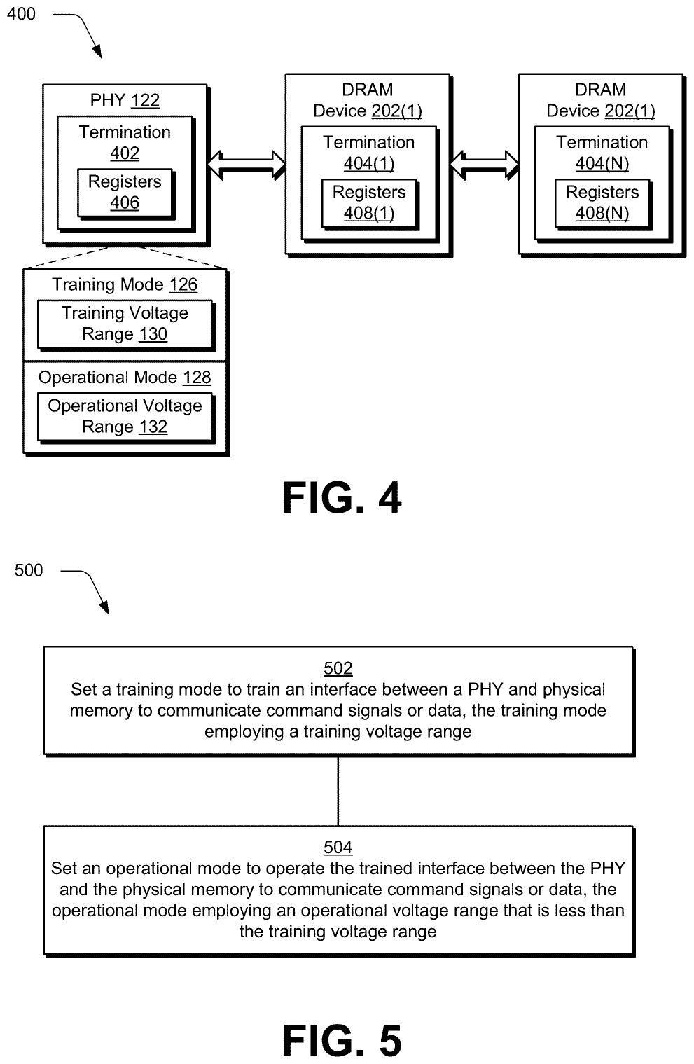

FIG. 4 is a block diagram of a non-limiting example system 400 showing individualized programmability of DRAM devices 202(1)-202(N) to implement the training voltage range 130 of the training mode 126 and the operational voltage range 132 of the operational mode 128. The PHY 122 and each of the DRAM devices 202(1)-202(N) are configurable to include a termination 402, 404(1), 404(N) and registers 406, 408(1)-408(N) that are independently programmable, e.g., for different voltage ranges. Independent programmability by the PHY 122 supports individualized training.

The DRAM devices 202(1)-202(N), for instance, include registers 408(1)-408(N) that are programmable to different values. Examples of these registers and corresponding functionality include default mode registers (e.g., RTT_Park), registers specifying a resistance at which signals sending write commands to the physical memory 110 terminate (e.g., RTT_WR), and so on. Each DRAM device 202(1)-202(N) that shares a communicative coupling (e.g., via a wire) is commonly referred to as a “rank.” Therefore, training a particular rank involves changing terminations between these various states individually to control “which” rank is being trained along that communicative coupling. A variety of other examples are also contemplated.

FIG. 5 depicts a procedure 500 in an example implementation of a step-wise algorithm that provides structure for training and operation mode voltage ranges for a physical interface communicatively coupling a physical layer (PHY) with physical memory.

A training mode is set to train an interface between a PHY and physical memory to communicate command signals or data. The training mode employs a training voltage range (block 502). By way of example, the PHY 122 sets a training voltage range 130 at the PHY 122 and/or individual DRAM devices 202(1)-202(N) by setting termination states or output impedances using a corresponding transistor.

An operational mode is set to operate the trained interface between the PHY and the physical memory to communicate command signals or data. The operational mode employs an operational voltage range that is less than the training voltage range (block 504). By way of example, the operational mode 128 employs parameters that are trained as part of the training mode 126. The operational mode 128 then uses these parameters at an operational voltage range 132 that is smaller than the training voltage range 130 of the training mode 126 which is also set by a corresponding transistor. In this way, a higher frequency is supported as part of the operational mode 128 that benefits from decreased training time of the training mode 126 that operates at a lower frequency. A variety of other examples are also contemplated.

It should be understood that many variations are possible based on the disclosure herein. Although features and elements are described above in particular combinations, each feature or element is usable alone without the other features and elements or in various combinations with or without other features and elements.

The various functional units illustrated in the figures and/or described herein (including, where appropriate, the device 102) are implemented in any of a variety of different manners such as hardware circuitry, software or firmware executing on a programmable processor, or any combination of two or more of hardware, software, and firmware. The methods provided are implemented in any of a variety of devices, such as a general purpose computer, a processor, or a processor core. Suitable processors include, by way of example, a general purpose processor, a special purpose processor, a conventional processor, a digital signal processor (DSP), a graphics processing unit (GPU), a parallel accelerated processor, a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

In one or more implementations, the methods and procedures provided herein are implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Although the systems and techniques have been described in language specific to structural features and/or methodological acts, it is to be understood that the systems and techniques defined in the appended claims are not necessarily limited to the specific features or acts described. Rather, the specific features and acts are disclosed as example forms of implementing the claimed subject matter.

What is claimed is:

1. A device comprising:
a physical layer (PHY) having an interface to support communication of command signals and data with a physical memory, the PHY implementing:
a training mode to train the interface over a training voltage range to communicate the command signals or data; and
an operational mode to use the trained interface to communicate the command signals or data over an operational voltage range that is smaller than the training voltage range.

2. The device of claim 1, wherein the interface implements an interface protocol that employs a parameter used to control communication of the command signals and the data with the physical memory.

3. The device of claim 2, wherein the training mode detects a value of the parameter of the interface protocol and the operational mode uses the detected parameter.

4. The device of claim 2, wherein the parameter involves signal or timing.

5. The device of claim 2, wherein the parameter involves voltage reference (Vref) training, command training, clock-to-strobe leveling, write-leveling training, or strobe-to-DQ training of the interface protocol.

6. The device of claim 2, wherein the parameter involves how signals are propagated from one physical memory component of the physical memory to another physical memory component of the physical memory.

7. The device of claim 1, wherein the training mode is configured to modify termination states or output impedances of the PHY to implement the training voltage range of the training mode.

8. The device of claim 1, wherein the training mode is further configured to modify termination states or output impedances of the physical memory to implement the training voltage range as part of the training mode.

9. The device of claim 1, wherein the training mode operates at a frequency that is lower than a frequency of the operational mode.

10. The device of claim 1, wherein the PHY includes another interface to transfer command signals and data with a memory controller.

11. The device of claim 1, wherein the PHY is implemented in hardware as part of an integrated circuit, the interface is bidirectional, and the physical memory is a dynamic random access memory (DRAM).

12. A system comprising:
a memory controller;
a dynamic random access memory (DRAM); and
a physical layer (PHY) providing a communicative coupling with the memory controller and the DRAM, the PHY implementing:
a training mode to detect a value of a parameter as part of training an interface between the PHY and the DRAM, the training mode operational over a training voltage range; and
an operational mode to use the detected value for the parameter to implement the interface between the PHY and the DRAM, the operational mode operational over an operational voltage range that is smaller than the training voltage range.

13. The system of claim 12, wherein the training mode is configured to modify termination states and output impedances of the PHY to implement the training voltage range of the training mode.

14. The system of claim 13, wherein the training mode is further configured to modify termination states and output impedances of the dynamic random access memory (DRAM) to implement the training voltage range as part of the training mode.

15. The system of claim 12, wherein the parameter includes signal or timing.

16. The system of claim 12, wherein the parameter includes voltage reference (Vref) training.

17. The system of claim 12, wherein the parameter includes command training, clock-to-strobe leveling, or strobe-to-DQ training.

18. A method comprising:
setting a training mode to train an interface between a physical layer (PHY) and physical memory to communicate command signals or data, the training mode employing a training voltage range; and
setting an operational mode to operate the trained interface between the PHY and the physical memory to communicate command signals or data, the operational mode employing an operational voltage range that is less than the training voltage range.

19. The method of claim 18, wherein the training mode is configured to modify termination states and output impedances of the PHY to implement the training voltage range of the training mode.

20. The method of claim 18, wherein the training of the interface is voltage reference (Vref) training.
